(19) United States
(12) Patent Application Publication
(10) Pub. No.: US 2024/0067026 A1
(43) Pub. Date: Feb. 29, 2024

(54) BATTERY MANAGEMENT SYSTEM AND VEHICLE

(71) Applicant: ISUZU MOTORS LIMITED, Yokohama-shi (JP)

(72) Inventor: Ryoma NISHIMURA, Fujisawa-shi (JP)

(21) Appl. No.: 18/456,918

(22) Filed: Aug. 28, 2023

(30) Foreign Application Priority Data
Aug. 30, 2022 (JP) 2022-137255

(51) Int. Cl. B60L 53/62; G01R 19/165; H02J 7/00

(52) U.S. Cl. CPC B60L 53/62; G01R 19/16542; H02J 7/0047; B60L 58/10

(57) ABSTRACT

Provided are a battery management system and a vehicle that correct an offset in a current measurement device even in a case where a charging/discharging current is constantly changing. The battery management system includes: an acquisition section that acquires, in a case where a charging current flowing from a charger to a battery is measured by a current measurement device, a measurement value measured by the current measurement device; a current value calculation section that calculates a current value of the charging current based on a known value of a current flowing from the charger; and a correction section that corrects an offset in the current measurement device based on the current value having been calculated and the measurement value.

### TECHNICAL FIELD

The present disclosure relates to a battery management system and a vehicle.

### BACKGROUND ART

For example, Patent Literature (hereinafter referred to as “PTL”) 1 discloses a technique of correcting, based on a measurement value of a current measured by a current measurement device on a side of a charging facility and a measurement value of a current measured by a current measurement device on a side of a vehicle, the measurement value measured by the current measurement device on the side of the vehicle.

### CITATION LIST

### Patent Literature

PTL 1
Japanese Patent Application Laid-Open No. 2014-230412

### SUMMARY OF INVENTION

### Technical Problem

Note that, there is a method of correcting an offset in a current measurement device in a state in which a current value is known, such as correction of an offset when a charging/discharging current of a battery is zero, as a timing of correcting an offset in a current measurement device.

In a case where the above-described method of correcting an offset is applied to equipment in which a charging/discharging current does not become zero and is constantly changing, however, it is difficult to take a timing of correction.

An object of the present disclosure is to provide a battery management system and a vehicle each capable of correcting an offset in a current measurement device even in a case where a charging/discharging current is constantly changing.

### Solution to Problem

In order to achieve the above-mentioned object, a battery management system of the present disclosure includes: an acquisition section that acquires, in a case where a charging current flowing from a charger to a battery is measured by a current measurement device, a measurement value measured by the current measurement device; a current value calculation section that calculates a current value of the charging current based on a known value of a current flowing from the charger; and a correction section that corrects an offset in the current measurement device based on the current value having been calculated and the measurement value.

A vehicle of the present disclosure includes: the battery and an auxiliary machine which are mounted in the vehicle; and the battery management system.

### Advantageous Effects of Invention

According to the present disclosure, it is possible to correct an offset in a current measurement device even when a charging/discharging current is constantly changing.

### BRIEF DESCRIPTION OF DRAWINGS

FIG. 1 schematically illustrates a configuration of an EV drive system according to an embodiment of the present disclosure;

FIG. 2 is a block diagram illustrating a configuration of a control section according to the embodiment of the present disclosure; and

FIG. 3 is a flowchart illustrating an exemplary operation of the control section according to the present embodiment.

### DESCRIPTION OF EMBODIMENTS

Hereinafter, an embodiment of the present disclosure will be described with reference to the accompanying drawings.

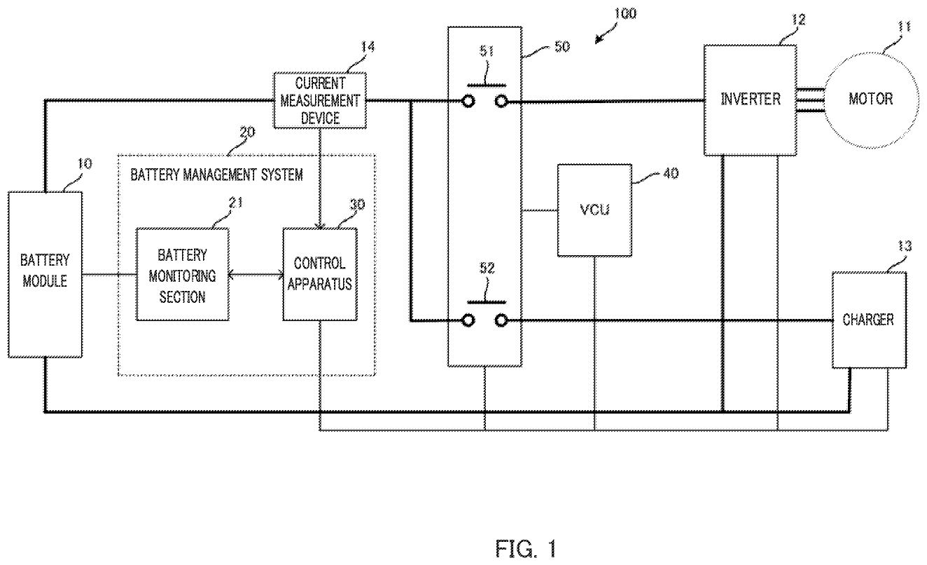

FIG. 1 schematically illustrates a configuration of EV drive system 100 according to an embodiment of the present disclosure. EV drive system 100 according to the embodiment of the present disclosure includes battery module 10, motor 11, inverter 12, charger 13, current measurement device 14, battery management system 20, vehicle control unit (VCU) 40, and junction box 50. Note that, EV drive system 100 according to the embodiment of the present disclosure is applied to an electric vehicle (EV), but the present disclosure is not limited thereto. EV drive system 100 according to the embodiment of the present disclosure may be applied to a plug-in hybrid electric vehicle, a hybrid vehicle, a forklift, an industrial robot, and a storage battery system.

Battery module 10 is formed of a plurality of battery cells (not illustrated) connected in series. The battery cell is produced by, for example, alternately combining a positive electrode plate and a negative electrode plate and injecting an electrolyte therein.

Motor 11 is connected to battery module 10 via inverter 12.

Motor 11 includes a stator and a rotor. The stator is fixed to a side of a case. The rotor is a rotating body that receives a current flowing through the stator as rotational energy.

Inverter 12 is an apparatus that converts DC power, which is the output of battery module 10, into an AC current that drives motor 11.

Charger 13 includes a connector (not illustrated) and the connector is connected to a port (charging port) of the EV. Thus, power is supplied from charger 13 to battery module 10 and battery module 10 can be charged. Further, power is supplied from charger 13 to an auxiliary machine (not illustrated). Note that, the auxiliary machine includes an auxiliary machine battery as a power supply for performing vehicle control.

VCU 40 is an apparatus that determines a state of a vehicle and controls each component, such as inverter 12, in order to maintain the vehicle in an optimum state. For example, VCU 40 executes control such that current value Iₖ whose current flows from charger 13 is adjusted in a constant current region.

Junction box 50 includes relay circuits 51 and 52. Battery module 10 and inverter 12 are connected via relay circuit 51. Charger 13 and battery module 10 are connected via relay circuit 52.

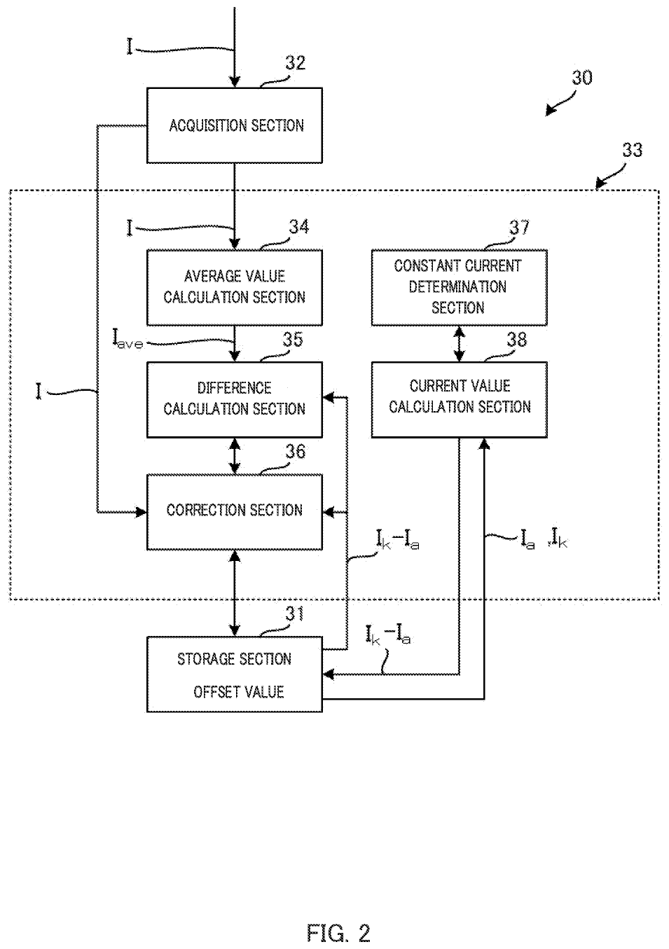

Current measurement device 14 measures a charging/discharging current of battery module 10. Measurement value I (see FIG. 2) measured by current measurement device 14 is transmitted to battery management system 20 at a predetermined time interval.

Battery management system 20 according to the embodiment of the present disclosure is a system that utilizes battery module 10 safely and efficiently.

Battery management system 20 includes battery monitoring section 21 and control apparatus 30.

Battery monitoring section 21 monitors a state of charge (SOC) of battery module 10. Further, battery monitoring section 21 measures a terminal voltage of battery module 10 (hereinafter simply referred to as terminal voltage) and an ambient temperature of battery module 10 (hereinafter simply referred to as ambient temperature). Further, battery monitoring section 21 transmits a terminal volt, an ambient temperature, and an SOC to control apparatus 30.

FIG. 2 is a block diagram illustrating a configuration of the control apparatus according to the embodiment of the present disclosure.

Control apparatus 30 includes storage section 31, acquisition section 32, and control section 33.

Storage section 31 is a storage medium including a read only memory (ROM), a random access memory (RAM), a hard disk, and the like. Storage section 31 stores a program that is executed by control section 33. Further, storage section 31 stores current value Iₐ whose current flows from charger 13 to the auxiliary machine and which is known. Further, storage section 31 stores current value Iₖ whose current flows from charger 13. Further, storage section 31 stores an offset (also referred to as offset value).

Acquisition section 32 acquires measurement value I transmitted from current measurement device 14 to battery management system 20 at a predetermined time interval. Further, acquisition section 32 acquires a terminal voltage, an ambient temperature, and a state of charge (SOC) that are transmitted from battery monitoring section 21.

There is a method of correcting an offset in current measurement device 14 in a state in which a current value is known, such as correction of an offset when a charging/discharging current of battery module 10 is zero, as a timing of correcting an offset in current measurement device 14. In a case where the above-described method of correcting an offset is applied to a drive system in which a charging/discharging current does not become zero and is constantly changing, however, it is difficult to take a timing of correction.

Control section 33 according to the present embodiment includes average value calculation section 34, difference calculation section 35, correction section 36, constant current determination section 37, and current value calculation section 38.

Control section 33 is a calculation resource including a processor such as a central processing unit (CPU), for example. Control section 33 implements functions of control section 33 by executing a program stored in storage section 31.

Average value calculation section 34 calculates average value Iₐᵥₑ of a predetermined plurality of measurement values I acquired by acquisition section 32.

Constant current determination section 37 determines based on control information of VCU 40 whether current value Iₖ whose current flows from charger 13 is a current value in a constant current region (a known current value) adjusted with high accuracy.

In a case where current value Iₖ is a current value in a constant current region (a known current value), current value calculation section 38 calculates a current value (Iₖ-Iₐ) by subtracting current value Iₐ, which is known, from current value Iₖ, which is known. The current value (Iₖ-Iₐ) is stored in storage section 31.

Difference calculation section 35 calculates a difference between a current value (Iₖ-Iₐ) and average value lave.

In a case where the calculated difference exceeds a predetermined range, correction section 36 corrects an offset in current measurement device 14. Note that, the predetermined range is set in advance based on, for example, the performance and characteristics of current measurement device 14. Correction section 36 corrects an offset based on a current value (Iₖ-Iₐ).

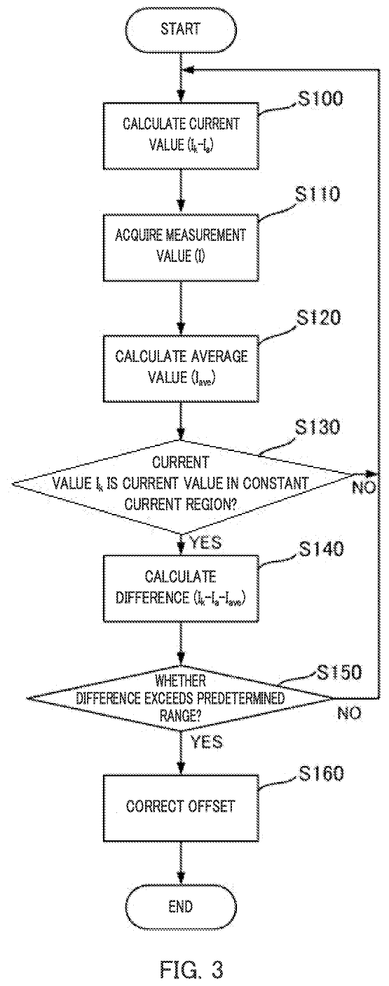

Next, an exemplary operation of control section 33 according to the present embodiment will be described with reference to FIG. 3. FIG. 3 is a flowchart illustrating an exemplary operation of the control section according to the present embodiment. This flow starts when the connector of charger 13 is connected to the port (charging port) of the EV. Note that, the following description will be given on the assumption that the functions of control section 33 are implemented by the CPU. The CPU acquires current value Iₖ whose current flows from charger 13 and current value Iₐ whose current flows from charger 13 to the auxiliary machine.

First, in step S100, in a case where current value Iₖ is a current value in a constant current region (a known current value), the CPU calculates a current value (Iₖ-Iₐ) obtained by subtracting current value Iₐ from current value Iₖ which is known. Storage section 31 stores the current value (Iₖ-Iₐ).

Next, in step S110, the CPU acquires measurement value I transmitted from current measurement device 14 to battery management system 20 at a predetermined time interval.

Next, in step S120, the CPU calculates average value Lave of a predetermined plurality of measurement values I.

Next, in step S130, the CPU determines whether current value Iₖ whose current flows from charger 13 is a current value in a constant current region (a known current value) adjusted with high accuracy. In a case where current value Iₖ is a current value in the constant current region (step S130: YES), the processing transitions to step S140. In a case where current value Iₖ is not a current value in the constant current region (step S130: NO), the processing returns to step S100.

In step S140, the CPU calculates a difference between the current value (Iₖ-Iₐ) and average value Iₐᵥₑ.

Next, in step S150, the CPU determines whether the difference exceeds a predetermined range. In a case where the difference exceeds the predetermined range (step S150: YES), the processing transitions to step S160. In a case where the difference does not exceed the predetermined range (step S150: NO), the processing returns to step S100.

Next, in step S160, the CPU corrects an offset in current measurement device 14. Thereby, the CPU acquires new measurement value I from current measurement device 14 after the offset correction. Thereafter, this flow ends.

Battery management system 20 according to the embodiment described above includes: acquisition section 32 that acquires, in a case where a charging current flowing from charger 13 to battery module 10 is measured by current measurement device 14, measurement value I measured by current measurement device 14; average value calculation section 34 that calculates average value Iₐᵥₑ of measurement values I; constant current determination section 37 that determines whether current value Iₖ whose current flows from charger 13 is a current value in a constant current region (a known current value); current value calculation section 38 that calculates a current value (Iₖ-Iₐ) of the charging current flowing to battery module 10 based on current value Iₖ, which is known, and current value Iₐ whose current flows from charger 13 to an auxiliary machine and which is known; difference calculation section 35 that calculates a difference between the current value (Iₖ-Iₐ) and average value which have been calculated; and correction section 36 that corrects an offset in current measurement device 14 in a case where the difference exceeds a predetermined range.

According to the configuration described above, even in a case where a charging/discharging current is constantly changing, it is possible to calculate a current value (Iₖ-Iₐ) and to correct an offset in current measurement device 14 based on the current value (Iₖ-Iₐ) when current value Iₖ whose current flows from charger 13 is a current value in a constant current region (a known current value) and current value Iₐ whose current flows from charger 13 to the auxiliary machine is a known current value. Further, since an opportunity for correction is provided in addition to offset correction by an offset analyzer, the current measurement accuracy by current measurement device 14 can be improved.

Further, since a difference between a current value (Iₖ-Iₐ) and average value Iₐᵥₑ is calculated and an offset is corrected based on the difference, offset correction can be performed at a more appropriate timing in comparison with a cases where the difference between the current value (Iₖ-Iₐ) and measurement value I is calculated. Further, since correction section 36 corrects an offset in a case where the difference exceeds a predetermined range, and the predetermined range is set based on the performance and characteristics of current measurement device 14, it is possible to perform offset correction at a precise timing.

Further, in battery management system 20 described above, a current value (Iₖ-Iₐ) is calculated based on current value Iₐ whose current flows from charger 13 to the auxiliary machine and which is known. In the present disclosure, however, a current value (Iₖ-Iₐ) may be calculated not only based on current value Iₐ whose current flows from charger 13 to the auxiliary machine and which is known, but also based on any other current value Iₐ which is known.

In addition, any of the embodiment described above is only illustration of an exemplary embodiment for implementing the present disclosure, and the technical scope of the present disclosure shall not be construed limitedly thereby. That is, the present disclosure can be implemented in various forms without departing from the gist or the main features thereof.

The present application is based on a Japanese Patent Application (Japanese Patent Application No. 2022-137255) filed on Aug. 30, 2022, the entire content of which is incorporated herein by reference.

### INDUSTRIAL APPLICABILITY

The present disclosure is suitably utilized in an EV power system including a battery management system required to correct an offset in a current measurement device even in a case where a charging/discharging current is constantly changing.

### REFERENCE SIGNS LIST

10 Battery module
11 Motor
12 Inverter
13 Charger
14 Current measurement device
20 Battery management system
21 Battery monitoring section
30 Control apparatus
31 Storage section
32 Acquisition section
33 Control section
34 Average value calculation section
35 Difference calculation section
36 Correction section
37 Constant current determination section
38 Current value calculation section
40 VCU
50 Junction box
51 Relay circuit
52 Relay circuit
100 EV drive system

1. A battery management system, comprising:
an acquisition section that acquires, in a case where a charging current flowing from a charger to a battery is measured by a current measurement device, a measurement value measured by the current measurement device;
a current value calculation section that calculates a current value of the charging current based on a known value of a current flowing from the charger; and
a correction section that corrects an offset in the current measurement device based on the current value having been calculated and the measurement value.

2. The battery management system according to claim 1, further comprising an average value calculation section that calculates an average value of a plurality of measurement values, wherein
the correction section corrects the offset in the current measurement device in a case where a difference between the current value and the average value exceeds a predetermined range, the current value and the average value having been calculated.

3. The battery management system according to claim 1, wherein the current value calculation section further calculates the current value based on a known value of a current flowing from the charger to an auxiliary machine.

4. A vehicle, comprising:
the battery and the auxiliary machine which are mounted in the vehicle; and
the battery management system according to claim 3.
